(19) United States
(12) Patent Application Publication
(10) Pub. No.: US 2016/0333221 A1
(43) Pub. Date: Nov. 17, 2016

(54) PROCESS THAT ENABLES THE CREATION OF NANOMETRIC STRUCTURES BY SELF-ASSEMBLY OF BLOCK COPOLYMERS

(71) Applicants: CENTRE NATIONAL DE LA RECHERCHE SCIENTIFIQUE (CNRS), Paris Cedex 14 (FR); UNIVERSITE DE BORDEAUX, Bordeaux (FR); INSTITUT POLYTECHNIQUE DE BORDEAUX, Talence Cedex (FR); ARKEMA FRANCE, Colombes (FR)

(72) Inventors: Muhammad MUMTAZ, Bordeaux (FR); Karim AISSOU, Gradignan (FR); Cyril BROCHON, Merignac (FR); Eric CLOUTET, Saint Caprais De Bordeaux (FR); Guillaume FLEURY, Bordeaux (FR); Georges HADZIIOANNOU, Leognan (FR); Christophe NAVARRO, Bayonne (FR); Celia NICOLET, Orthez (FR); Xavier CHEVALIER, Grenoble (FR)

(73) Assignees: CENTRE NATIONAL DE LA RECHERCHE SCIENTIFIQUE (CNRS), Paris Cedex 14 (FR); UNIVERSITE DE BORDEAUX, Bordeaux (FR); INSTITUT POLYTECHNIQUE DE BORDEAUX, Talence Cedex (FR); ARKEMA FRANCE, Colombes (FR)

(21) Appl. No.: 15/103,740

(22) PCT Filed: Dec. 11, 2014
(86) PCT No.: PCT/FR2014/053279

§ 371 Date: Jun. 10, 2016

(30) Foreign Application Priority Data
Dec. 13, 2013 (FR) 13.62597

(51) Int. Cl. C09D 183/00; G03F 7/00; B81C 1/00; C08G 77/00

(52) U.S. Cl. CPC C09D 183/00; C08G 77/00; G03F 7/0002; B81C 1/00428

(57) ABSTRACT

The invention relates to a process that enables the creation of nanometric structures by self-assembly of block copolymers, at least one of the blocks of which is crystallizable or has at least one liquid crystal phase.

The invention relates to a process that enables the creation of nanometric structures by self-assembly of block copolymers, at least one of the blocks of which is crystallizable or has at least one liquid crystal phase.

The invention also relates to the use of these materials in the fields of lithography (lithography masks), information storage but also the production of porous membranes or as catalyst support. The invention also relates to the block copolymer masks obtained according to the process of the invention.

The development of nanotechnologies has made it possible to constantly miniaturize products in the field of microelectronics and micro-electro-mechanical systems (MEMS) in particular. Today, conventional lithography techniques no longer make it possible to meet these constant needs for miniaturization, as they do not make it possible to produce structures with dimensions of less than 60 nm.

It has therefore been necessary to adapt the lithography techniques and create etching masks that make it possible to create increasingly small patterns with a high resolution. With the block copolymers it is possible to structure the arrangement of the constituent blocks of the copolymers, by phase segregation between the blocks thus forming nanodomains, on scales of less than 50 nm. Due to this ability to be nanostructured, the use of block copolymers in the fields of electronics or optoelectronics is now well known.

Among the masks studied for carrying out nanolithography, block copolymer films, in particular based on polystyrene-poly(methyl methacrylate), denoted hereinbelow as PS-b-PMMA, appear to be very promising solutions since they make it possible to create patterns with a high resolution. In order to be able to use such a block copolymer film as an etching mask, one block of the copolymer must be selectively removed in order to create a porous film of the residual block, the patterns of which may be subsequently transferred by etching to an underlying layer. Regarding the PS-b-PMMA film, the minority block, that is to say the PMMA (poly(methyl methacrylate)) is removed selectively in order to create a mask of residual PS (polystyrene).

In order to create such masks, the nanodomains must be oriented perpendicular to the surface of the underlying layer. Such structuring of the domains requires particular conditions such as the preparation of the surface of the underlying layer, but also the composition of the block copolymer.

The ratios between the blocks make it possible to control the shape of the nanodomains and the molecular mass of each block makes it possible to control the dimension of the blocks. Another very important factor is the phase segregation factor, also referred to as the Flory-Huggins interaction parameter and denoted by “χ”. Specifically, this parameter makes it possible to control the size of the nanodomains. More particularly, it defines the tendency of the blocks of the block copolymer to separate into nanodomains. Thus, the product χN of the degree of polymerization, N, and of the Flory-Huggins parameter χ, gives an indication as to the compatibility of two blocks and whether they may separate. For example, a diblock copolymer of symmetrical composition separates into microdomains if the product χN is greater than 10. If this product χN is less than 10, the blocks mix together and phase separation is not observed.

Due to the constant needs for miniaturization, it is sought to increase this degree of phase separation, in order to produce nanolithography masks that make it possible to obtain very high resolutions, typically of less than 20 nm, and preferably of less than 10 nm.

In Macromolecules, 2008, 41, 9948, Y. Zhao et al. estimated the Flory-Huggins parameter for a PS-b-PMMA block copolymer. The Flory-Huggins parameter χ obeys the following equation: χ=a+b/T, where the values a and b are constant specific values dependent on the nature of the blocks of the copolymer and T is the temperature of the heat treatment applied to the block copolymer in order to enable it to organise itself, that is to say in order to obtain a phase separation of the domains, an orientation of the domains and a reduction in the number of defects. More particularly, the values a and b respectively represent the entropic and enthalpic contributions. Thus, for a PS-b-PMMA block copolymer, the phase segregation factor obeys the following equation: χ=0.0282+4.46/T. Consequently, even though this block copolymer makes it possible to generate domain sizes of slightly less than 20 nm, it does not make it possible to go down much lower in terms of domain size, due to the low value of its Flory-Huggins interaction parameter χ.

This low value of the Flory-Huggins interaction parameter therefore limits the advantage of block copolymers based on PS and PMMA for the production of structures having very high resolutions.

In order to get round this problem, M. D. Rodwogin et al., ACS Nano, 2010, 4, 725, demonstrated that it is possible to change the chemical nature of the two blocks of the block copolymer in order to very greatly increase the Flory-Huggins parameter χ and to obtain a desired morphology with a very high resolution, that is to say the size of the nanodomains of which is less than 20 nm. These results have in particular been demonstrated for a PLA-b-PDMS-b-PLA (polylactic acid-polydimethylsiloxane-polylactic acid) triblock copolymer.

H. Takahashi et al., Macromolecules, 2012, 45, 6253, studied the influence of the Flory-Huggins interaction parameter χ on the kinetics of the copolymer assembly and of reduction of defects in the copolymer. They have in particular demonstrated that when this parameter χ becomes too large, there is generally a significant slowing down of the assembly kinetics, of the phase segregation kinetics also leading to a slowing down of the kinetics of defect reduction at the moment of the organization of the domains. Another problem, reported by S. Ji et al., ACS Nano, 2012, 6, 5440, is also faced when considering the organisation kinetics of block copolymers containing a plurality of blocks that are all chemically different from one another. Specifically, the kinetics of diffusion of the polymer chains, and hence also the kinetics of organization and defect reduction within the self-assembled structure, are dependent on the segregation parameters χ between each of the various blocks. Moreover, these kinetics are also slowed down due to the multiblock nature of the copolymer, since the polymer chains then have fewer degrees of freedom for becoming organized with respect to a block copolymer comprising fewer blocks.

Patents U.S. Pat. No. 8,304,493 and U.S. Pat. No. 8,450,418 describe a process for modifying block copolymers, and also modified block copolymers. These modified block copolymers have a modified value of the Flory-Huggins interaction parameter χ, such that the block copolymer has nanodomains of small sizes.

Due to the fact that PS-b-PMMA block copolymers already make it possible to achieve dimensions of the order of 20 nm, the Applicant has sought a solution for modifying this type of block copolymer in order to obtain a good compromise regarding the Flory-Huggins interaction parameter χ, and the self-assembly speed and temperature.

Surprisingly, it has been discovered that a block copolymer, at least one of the blocks of which is crystallizable or has at least one liquid crystal phase, has the following advantages when it is deposited on a surface:
Rapid self-assembly kinetics (between 1 and 20 minutes) for low molecular masses leading to domain sizes well below nm, at low temperatures (between 333 and 603 K and preferably between 373 K and 603 K).
The orientation of the domains during the self-assembly of such block copolymers does not require preparation of the support (no neutralization layer), the orientation of the domains being governed by the thickness of the block copolymer film deposited.

Thus, these materials show a very great advantage for applications in nanolithography for the production of etching masks of very small dimensions and that have a good etching contrast, and also the production of porous membranes or else as catalyst support.

### SUMMARY OF THE INVENTION

The invention relates to a nanostructured assembly process using a composition comprising a block copolymer, at least one of the blocks of which is crystallizable or has at least one liquid crystal phase, and comprising the following steps:
dissolving the block copolymer in a solvent,
depositing this solution on a surface,
annealing.

### DETAILED DESCRIPTION

The term “surface” is understood to mean a surface which can be flat or non-flat.

The term “annealing” is understood to mean a step of heating at a certain temperature that enables the evaporation of the solvent, when it is present, and that allows the establishment of the desired nanostructuring in a given time (self-assembly). The term “annealing” is also understood to mean the establishment of the nanostructuring of the block copolymer film when said film is subjected to a controlled atmosphere of one or more solvent vapors, these vapors giving the polymer chains sufficient mobility to become organized by themselves on the surface. The term “annealing” is also understood to mean any combination of the abovementioned two methods.

Any block copolymer, whatever its associated morphology, will be able to be used in the context of the invention, whether diblock, linear or star-branched triblock or linear, comb-shaped or star-branched multiblock copolymers are involved, on condition that at least blocks of the block copolymer is crystallizable or has at least one liquid crystal phase. Preferably, diblock or triblock copolymers and more preferably diblock copolymers are involved.

They may be synthesized by any techniques known to those skilled in the art, among which mention may be made of polycondensation, ring-opening polymerization, and anionic, cationic or radical polymerization, it being possible for these techniques to be controlled or uncontrolled. When the copolymers are prepared by radical polymerization, the latter may be controlled by any known technique, such as NMP (“Nitroxide Mediated Polymerization”), RAFT (“Reversible Addition and Fragmentation Transfer”), ATRP (“Atom Transfer Radical Polymerization”), INIFERTER (“Initiator-Transfer-Termination”), RITP (“Reverse Iodine Transfer Polymerization”) or ITP (“Iodine Transfer Polymerization”).

The term “block which is crystallizable or has at least one liquid crystal phase” is intended to mean a block which has at least one transition temperature measurable by differential scanning calorimetry, whether it is a crystal->smectic, smectic->nematic, nematic->isotropic, or crystal->isotropic liquid transition.

The block copolymer which has a liquid crystal block may be a block copolymer which has a block that is either lyotropic or thermotropic.

The block copolymer which has a crystallizable block may be a block copolymer which has a crystalline or semi-crystalline block.

The blocks which are crystallizable or which have at least one liquid crystal phase may be of any type, but they will preferably be chosen such that the Flory-Huggins parameter χ of the block copolymer is between 0.01 and 100 and preferably between 0.04 and 25.

The blocks which are not crystallizable or which do not have a liquid crystal phase consist of the following monomers: at least one vinyl, vinylidene, diene, olefinic, allyl or (meth)acrylic or cyclic monomer. These monomers are selected more particularly from vinylaromatic monomers, such as styrene or substituted styrenes, in particular α-methylstyrene, acrylic monomers, such as alkyl, cycloalkyl or aryl acrylates, such as methyl, ethyl, butyl, ethylhexyl or phenyl acrylate, ether alkyl acrylates, such as 2-methoxyethyl acrylate, alkoxy- or aryloxypolyalkylene glycol acrylates, such as methoxypolyethylene glycol acrylates, ethoxypolyethylene glycol acrylates, methoxypolypropylene glycol acrylates, methoxypolyethylene glycol-polypropylene glycol acrylates or mixtures thereof, aminoalkyl acrylates, such as 2-(dimethylamino)ethyl acrylate (ADAME), fluoroacrylates, phosphorus-comprising acrylates, such as alkylene glycol phosphate acrylates, glycidyl acrylate or dicyclopentenyloxyethyl acrylate, alkyl, cycloalkyl, alkenyl or aryl methacrylates, such as methyl (MMA), lauryl, cyclohexyl, allyl, phenyl or naphthyl methacrylate, ether alkyl methacrylates, such as 2-ethoxyethyl methacrylate, alkoxy- or aryloxypolyalkylene glycol methacrylates, such as methoxypolyethylene glycol methacrylates, ethoxypolyethylene glycol methacrylates, methoxypolypropylene glycol methacrylates, methoxypolyethylene glycol-polypropylene glycol methacrylates or mixtures thereof, aminoalkyl methacrylates, such as 2-(dimethylamino)ethyl methacrylate (MADAME), fluoromethacrylates, such as 2,2,2-trifluoroethyl methacrylate, silylated methacrylates, such as 3-methacryloylpropyltrimethylsilane, phosphorus-comprising methacrylates, such as alkylene glycol phosphate methacrylates, hydroxyethylimidazolidone methacrylate, hydroxyethylimidazolidinone methacrylate or 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamidopropyltrimethylammonium chloride (MAPTAC), glycidyl methacrylate, dicyclopentenyloxyethyl methacrylate, maleic anhydride, alkyl or alkoxy- or aryloxypolyalkylene glycol maleates or hemimaleates, vinylpyridine, vinylpyrrolidinone, (alkoxy)poly(alkylene glycol) vinyl ethers or divinyl ethers, such as methoxypoly(ethylene glycol) vinyl ether or poly(ethylene glycol) divinyl ether, olefinic monomers, among which may be mentioned ethylene, butene, hexene and 1-octene, diene monomers, including butadiene or isoprene, and also as fluoroolefinic monomers and vinylidene monomers, among which may be mentioned vinylidene fluoride, cyclic monomers, among which may be mentioned lactones such as e-caprolactone, lactides, glycolides, cyclic carbonates such as trimethylene carbonate, siloxanes such as octamethylcyclotetrasiloxane, cyclic ethers such as trioxane, cyclic amides such as e-caprolactam, cyclic acetals such as 1,3-dioxolane, phosphazenes such as hexachlorocyclotriphosphazene, N-carboxyanhydrides, phosphorus-comprising cyclic esters such as cyclophosphorinanes, cyclophospholanes or oxazolines, where appropriate protected in order to be compatible with anionic polymerization processes, alone or as a mixture of at least two abovementioned monomers.

Preferably, the blocks which are not crystallizable or which do not have a liquid crystal phase comprise methyl methacrylate in weight proportions of greater than 50% and preferably greater than 80% and more preferably greater than 95%.

Once the block copolymer has been synthesized, it is dissolved in a suitable solvent then deposited on a surface according to techniques known to a person skilled in the art such as for example the spin coating, doctor blade coating, knife coating system or slot die coating system technique, but any other technique may be used such as dry deposition, that is to say deposition without involving a predissolution. Films are thus obtained which have a thickness of less than 100 nm.

Mention will be made, among the favored surfaces, of silicon, silicon having a native or thermal oxide layer, hydrogenated or halogenated silicon, germanium, hydrogenated or halogenated germanium, platinum and platinum oxide, tungsten and oxides, gold, titanium nitrides and graphenes. Preferably, the surface is inorganic and more preferably silicon. More preferably still, the surface is silicon having a native or thermal oxide layer.

It will be noted in the context of the present invention, even though it is not excluded, that it is not necessary to carry out a neutralization step (as is the case generally in the prior art) by the use of a suitably chosen statistical copolymer. This presents a considerable advantage since this neutralization step is disadvantageous (synthesis of the statistical copolymer of particular composition, deposition on the surface). The orientation of the block copolymer is defined by the thickness of the block copolymer film deposited. It is obtained in a relatively short time, of between 1 and 20 minutes limits included and preferably of between 1 and 5 minutes, and at temperatures between 333 K and 603 K and preferably between 373 K and 603 K and more preferably between 373 K and 403 K.

The process of the invention applies advantageously to the field of nanolithography using block copolymer masks, or more generally to the field of surface nanostructuring for electronics.

The process of the invention also enables the manufacture of porous membranes or catalyst supports for which one of the domains of the block copolymer is degraded in order to obtain a porous structure.

### Example 1

### Synthesis of poly(1,1-dimethylsilacyclobutane)-block-PMMA (PDMSB-b-PMMA)

### 1,1-Dimethylsilacyclobutane (DMSB) is a monomer of formula (I) where X═Si(CH₃)₂, Y═Z=T=CH₂

The synthesis is performed using sequential anionic polymerization in a 50/50 vol/vol THF/heptane mixture at −50° C. with the secondary butyl lithium (sec-BuLi) initiator. Such a synthesis is well known to a person skilled in the art. A first block is prepared according to the protocol described by Yamaoka et coll., Macromolecules, 1995, 28, 7029-7031.

The following block is constructed in the same manner by sequentially adding the MMA, with a step of addition of 1,1-diphenylethylene for controlling the reactivity of the active center.

Typically, lithium chloride (85 mg), 20 ml of THF and 20 ml of heptane are introduced into a 250 ml flame-dried round-bottomed flask equipped with a magnetic stirrer. The solution is cooled to −50° C. Next, 0.00025 mol of sec-BuLi is introduced, followed by an addition of 0.01 mol of 1,1-dimethylsilacyclobutane. The reaction mixture is stirred for 1 h and then 0.2 ml of 1,1-diphenylethylene is added. 30 minutes later, 0.0043 mol of methyl methacrylate is added and the reaction mixture is kept stirring for 1 h. The reaction is completed by an addition of degassed methanol at −50° C. Next, the reaction medium is concentrated by evaporation, followed by a precipitation in methanol. The product is then recovered by filtration and dried in an oven at 35° C. overnight.

### Example 2

### Synthesis of poly(1-butyl-1-methylsilacyclobutane)-b-poly(methyl methacrylate)

This copolymer is prepared according to the protocol of example 1, by varying the amounts of the reactants and by using 1-butyl-1-methylsilacyclobutane (BMSB).

The molecular masses and the dispersities, corresponding to the ratio of weight-average molecular mass (Mw) to number-average molecular mass (Mn), are obtained by SEC (size exclusion chromatography), using two Agilent 3 μm ResiPore columns in series, in a THF medium stabilized with BHT, at a flow rate of 1 ml/min, at 40° C., with samples at a concentration of 1 g/l, with prior calibration with graded samples of polystyrene using an Easical PS-2 prepared pack. The results are given in table 1:

TABLE 1

| | | | | | | Polysiletane/ | |
|---|---|---|---|---|---|---|---|
| | | Mn SEC | sec | mole DMSB | mole | PMMA composition | Dispersity |
| copolymer | Example | (g/mol)) | BuLi | or BMSB | MMA | (wt %) | Mw/Mn |
| PDMSB49-b-PMMA17 | 1 (invention) | 6600 | 0.00025 | 0.01 | 0.0043 | 74/26 | 1.08 |
| PBMSB-b-PMMA | 2 (comparative) | 7150 | 0.00025 | 0.0067 | 0.01 | 63/37 | 1.10 |

The films from examples 1 and 2 were prepared by spin coating from a 1.5 wt % solution in toluene and the thickness of the film was controlled by varying the spin coating speed (from 1500 to 3000 rpm), typically less than 100 nm. The promotion of the self-assembly inherent to the phase segregation between the blocks of the copolymer was obtained by short annealings (5 min) on a hot plate at 453 K.

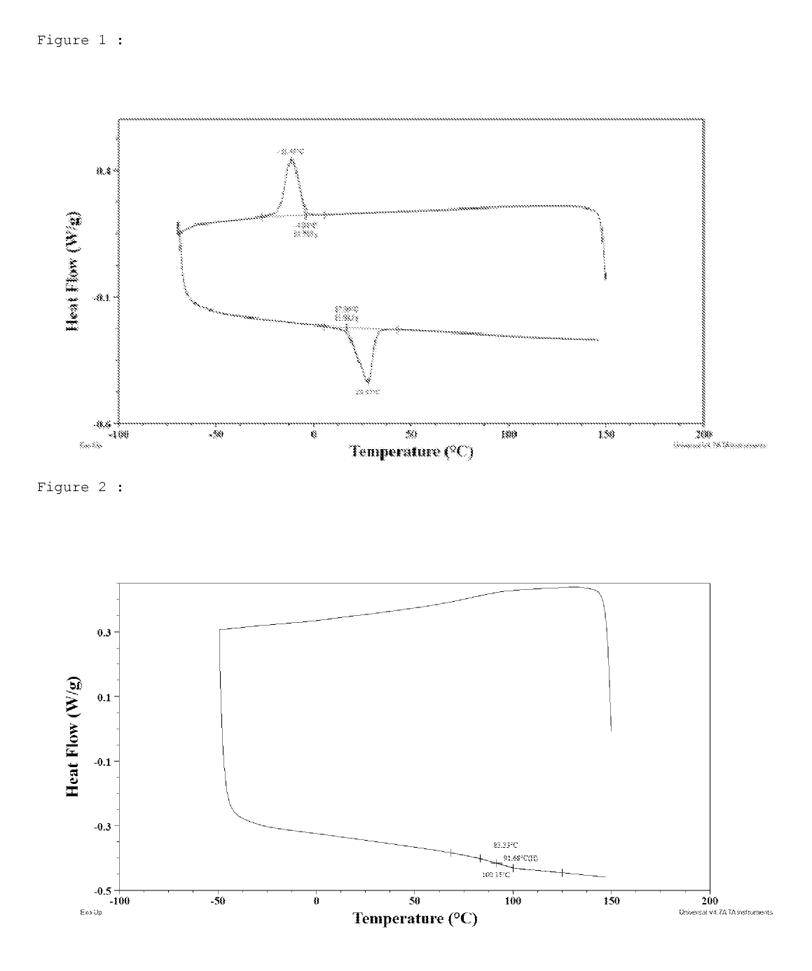

Although the copolymer of example 1 exhibits a phase transition which is clearly visible by DSC (FIG. 1), the copolymer of example 2 does not exhibit any transition, behaving in an amorphous manner (FIG. 2).

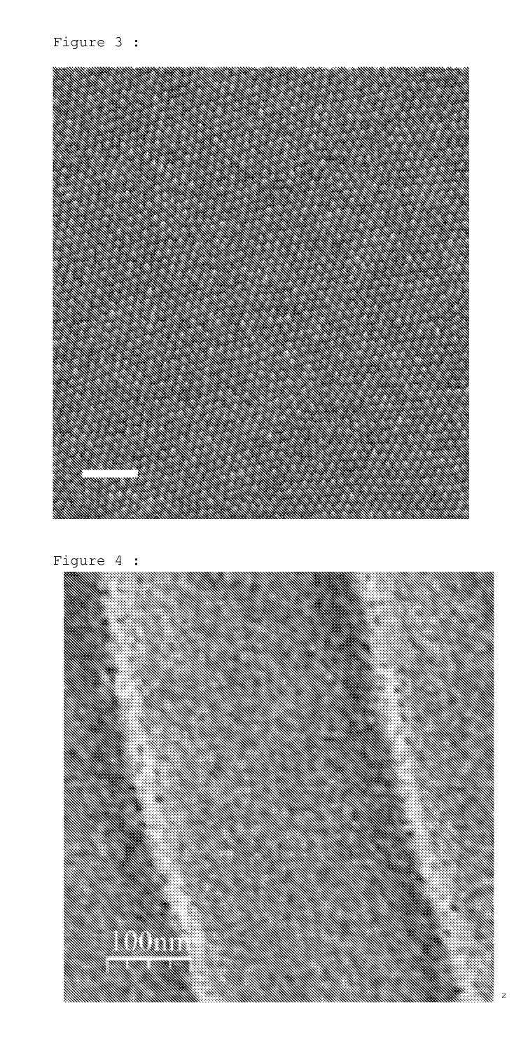

Copolymer 1 exhibits a self-assembly which is visible in FIG. 3, while copolymer 2 exhibits no self-assembly (FIG. 4).

FIG. 1 is a DSC of copolymer 1 during a heating-cooling-heating cycle under nitrogen at 10° C./min. The data presented represent the cooling and the second heating.

FIG. 2 is a DSC of copolymer 2 during a heating-cooling-heating cycle under nitrogen at 10° C./min. The data presented represent the cooling and the second heating.

FIG. 3 is a photo taken in AFM microscopy of a thin-film self-assembly, the film having a thickness of less than 100 nm, of the block copolymer from example 1 having cylinders oriented perpendicular to the substrate. Scale 100 nm.

FIG. 4 is a photo taken in AFM microscopy and shows the absence of self-assembly of the copolymer from example 6 as a thin film having a thickness of less than 100 nm, the lines are the guides that are used for the promotion of self-assembly in graphoepitaxy. Scale 100 nm.

1. A nanostructured assembly process using a composition comprising a block copolymer, at least one of the blocks of which is crystallizable or has at least one liquid crystal phase, wherein the process comprises the following steps:
dissolving the block copolymer in a solvent to form a solution,
depositing the solution on a surface,
annealing.

2. The process as claimed in claim 1, wherein the block copolymer is a diblock copolymer.

3. The process as claimed in claim 1, wherein the block copolymer has a crystallizable block.

4. The process as claimed in claim 1, wherein at least one of the blocks has a liquid crystal phase and the block which has a liquid crystal phase is lyotropic.

5. The process as claimed in claim 1, wherein at least one of the blocks has a liquid crystal phase and the block which has a liquid crystal phase is thermotropic.

6. The process as claimed in claim 1, wherein orientation of the block copolymer is carried out during a time of between 1 and 20 minutes, limits included.

7. The process as claimed in claim 1, wherein orientation of the block copolymer is carried out at a temperature of between 333 K and 603 K.

8. The process as claimed in claim 1, wherein orientation of the block copolymer is carried out under a controlled atmosphere comprising solvent vapors, or a solvent atmosphere/temperature combination.

9. The use of the process as claimed in claim 1 in the field of surface nanostructuring for electronics.

10. A mask of block copolymers obtained using the process as claimed in claim 1.
